(19) United States
(12) Patent Application Publication
(10) Pub. No.: US 2017/0110326 A1
(43) Pub. Date: Apr. 20, 2017

(54) SEMICONDUCTOR MANUFACTURING APPARATUS AND MANUFACTURING METHOD OF SEMICONDUCTOR DEVICE

(71) Applicant: Kabushiki Kaisha Toshiba, Minato-ku (JP)

(72) Inventors: Kazuya YOSHIMORI, Yokkaichi (JP); Yuji KUBO, Yokkaichi (JP); Kengo MATSUMOTO, Kuwana (JP); Shun SHIMABUKURO, Yokkaichi (JP)

(73) Assignee: Kabushiki Kaisha Toshiba, Minato-ku (JP)

(21) Appl. No.: 15/009,134

(22) Filed: Jan. 28, 2016

(30) Foreign Application Priority Data
Oct. 15, 2015 (JP) 2015-203643

(51) Int. Cl. H01L 21/3065; H01L 21/67; H01J 37/32; H01L 21/687

(52) U.S. Cl. CPC H01L 21/3065; H01L 21/68714; H01L 21/67069; H01J 37/32449; H01J 37/32623; H01J 2237/334

(57) ABSTRACT

According to one embodiment, a semiconductor manufacturing apparatus includes a chamber, a stage, and first gas injector. The chamber is configured to contain a wafer. The stage is configured to hold the wafer in the chamber. The first gas injector is set at N (N is an integer of 2 or more) injection angles with respect to a vertical axis relative to a wafer surface, and is capable of injecting a gas of one and the same kind from the side portion to the center of the wafer at the N injection angles.

### CROSS-REFERENCE TO RELATED APPLICATIONS

This application is based upon and claims the benefit of priority front Japanese Patent Application No. 2015-203643, filed on Oct. 15, 2015; the entire contents of which are incorporated herein by reference.

### FIELD

Embodiments described herein relate generally to a semiconductor manufacturing apparatus and a manufacturing method of a semiconductor device.

### BACKGROUND

In a process for manufacturing a semiconductor, an etching gas or a deposition gas is introduced onto a wafer at an etching step and a CVD step.

### BRIEF DESCRIPTION OF THE DRAWINGS

FIG. 1A is a schematic cross-sectional view of a semiconductor manufacturing apparatus according to a first embodiment, FIG. 1B is a top view illustrating an arrangement example of a gas injector over a wafer illustrated in FIG. 1A, FIG. 1C is an enlarged cross-sectional view of the gas injector illustrated in FIG. 1A, and FIG. 1D is a perspective view illustrating a configuration example of the gas injector illustrated in FIG. 1A;

FIGS. 2A and 2B are cross-sectional views illustrating a manufacturing method of a semiconductor device to which the semiconductor manufacturing apparatus illustrated in FIG. 1A is applied, and FIG. 2C is a diagram illustrating the relationship between line dimensions and wafer positions at the semiconductor device illustrated in FIG. 2B;

FIG. 3 is a schematic cross-sectional view of a semiconductor manufacturing apparatus according to a second embodiment;

FIG. 4 is a diagram illustrating an example of a gas injection control unit illustrated in FIG. 3;

FIG. 5 is a diagram illustrating another example of the gas injection control unit illustrated in FIG. 3;

FIG. 6 is a schematic cross-sectional view of a semiconductor manufacturing apparatus according to a third embodiment; and

FIG. 7 is a schematic cross-sectional view of a semiconductor manufacturing apparatus according to a fourth embodiment.

### DETAILED DESCRIPTION

In general, according to one embodiment, a semiconductor manufacturing apparatus includes a chamber, a stage, and a first gas injector. The chamber is configured to contain a wafer. The stage is configured to hold the wafer in the chamber. The first gas injector set at N (N is an integer of or more) injection angles with respect to a vertical axis relative to a wafer surface, and is capable of injecting a gas of one and the same kind from the side portion the center of the wafer at the N injection angles.

Exemplary embodiments of a semiconductor manufacturing apparatus and a manufacturing method of a semiconductor device will be explained below in detail with reference to the accompanying drawings. The present invention is not limited to the following embodiments.

### First Embodiment

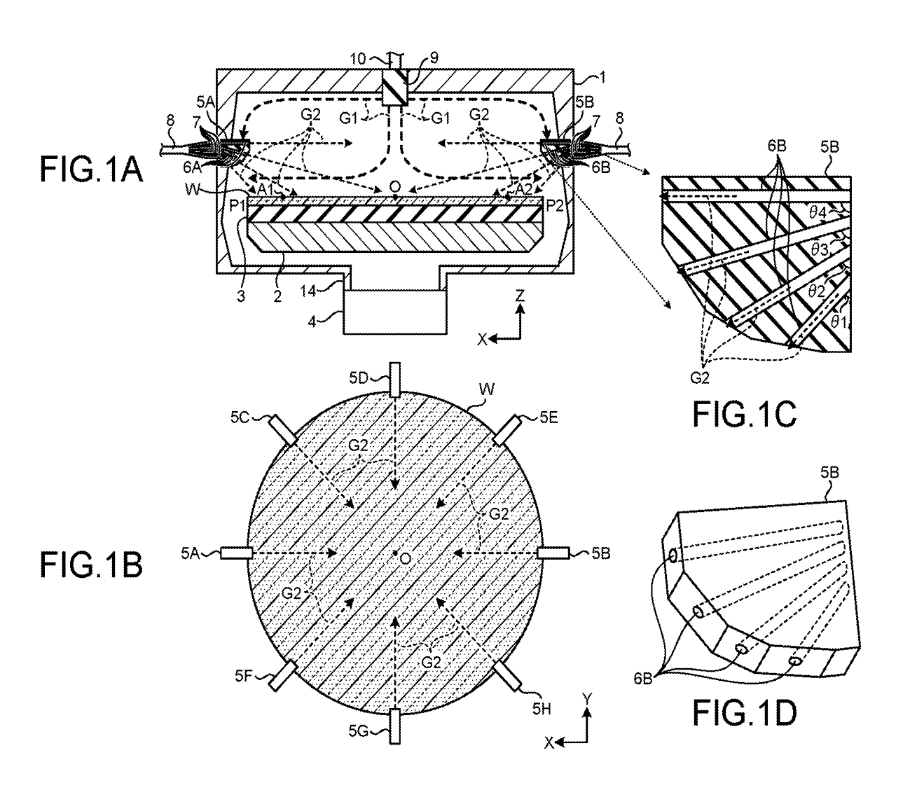

FIG. 1A is a Thematic cross-sectional view of semiconductor manufacturing apparatus according to a first embodiment, FIG. 1B is a top view illustrating an arrangement example of a gas injector over a wafer illustrated FIG. 1A, FIG. 1C is an enlarged cross-sectional view of the gas injector illustrated in FIG. 1A, and FIG. 1D is a perspective view illustrating a configuration example of the gas injector illustrated in FIG. 1A.

Referring to FIGS. 1A to 1D, a chamber 1 is provided with a stage 2 holding a wafer W. The chamber 1 contains the wafer W to isolate an atmosphere above the wafer W from the outside world. An electrostatic chuck 3 absorbing the wafer W is provided on the stage 2. An exhaust duct 14 is provided on the lower surface of the chamber 1. The exhaust duct 14 is connected to a vacuum pump 4. The vacuum pump 4 exhausts air from the chamber 1 via the exhaust duct 14 to maintain the inside of the chamber 1 at a predetermined degree of vacuum.

A gas injector 9 is placed on the top surface of the chamber 1, and as injectors 5A to 5H are placed on the side surface of the chamber 1. The gas injectors 5A to 5H can inject a gas G2 of one and the same kind from the side portion to a center O of the wafer W. The gas G2 of the one kind may be a gas of one and the same composition. The gas injectors 5A to 5H can be placed on the side portion of the wafer W at M (M is an integer of 2 or more, more preferably 3 or more) positions. FIG. 12 illustrates the example in which the gas injectors 5A to 5H are placed on the side portion of the wafer W at eight positions. The gas injectors 5A to 5H have (point) symmetry with respect to the center O of the wafer W, and desirably inject the gas 32 of one and the same kind at almost even flow amounts from the direction of M symmetric with respect to the center O of the wafer W.

In addition, as illustrated in FIG. 1A, for example, the as injectors 5A and 5B have nozzles 6A and 6B. When it is assumed that the wafer surface is placed on an XY plane and a vertical axis relative to the wafer surface is along a Z-axis direction, the nozzles 6A and 6B are set at N (N is an integer of 2 or more) injection angles relative to the S axis. FIGS. 1A and 1C illustrate the example in which the nozzles 6A and 6B are set at four injection angles θ1 to θ4 relative to the Z axis. At that time, the relationship θ4>θ3>θ2>θ1 can be satisfied. The injection angles θ1 to θ4 of the nozzles 6A and 6B can be set within one and the same plane vertical to the wafer surface. To provide the nozzles 6A and 6B with the gas injectors 5A and 5B, through holes may be formed in a polyhedral block of ceramic or the like, or pipes to be the nozzles 6A and 6B may be held by supporting bodies. The nozzles 6A and 6B at the injection angles θ1 to θ4 are respectively connected to corresponding branch tubes 7, and the branch tubes 7 join with main tubes 8. Nozzles 6C to 6H can be configured in the same manner as the nozzles 6A and 6B. The main tubes 8 can be connected to one and the same gas source. When the gas injectors 5A to 5H at the four injection angles θ1 to θ4 are arranged at the eight positions, the branch tubes 7 can divide the gas G2 sent from the main tubes 8 into 8×4 branches.

The gas injector 9 can inject a gas G1 from above the wafer W to the wafer surface and inject the gas G1 above the wafer N in a horizontal direction or an oblique direction. The gas injector 9 is connected to a pipe 10. The gas G1 may be a main gas that advances the process in the chamber 1. The process in the chamber 1 may be a plasma process, for example. The plasma process may be a plasma etching process or a plasma CVD process. In the plasma etching process, the gas G1 may be mainly an etching gas. In the plasma CVD process, the gas G1 may be mainly a deposition gas. The gas G2 may be a tuning gas that adjusts singularities in the flow of the gas G1 on the wafer surface. In the etching process, the dimensions of lines and the diameters of holes formed by the etching become uneven at the singularities in the flow of the gas G1. In addition, in a film forming process, films formed by CVD become uneven in thickness and quality at the singularities in the flow of the gas G1. The gas G2 can include at least one of an etching gas, a deposition gas, and a deposition removal gas.

The etching gas can be used to etch a film on the wafer W. The deposition gas can be used to form a film on the wafer W. The deposition removal gas can be used to remove the film formed by the deposition gas. In the etching process, the deposition gas may be used to form a protection film for protection from the etching. As the protection film, a carbon-based film may be used, for example. Introducing the deposition gas onto the wafer W to form the protection film on the side wall of a hole at the formation of the hole by anisotropic etching could improve the aspect ratio of the hole, for example. The etching gas may be a fluorocarbon gas such as CF₄, CHF₃, or C₄F₈, for example. The deposition gas may be a fluorocarbon gas or a hydrocarbon gas such as C₄F₆ or CG₄, for example. The deposition removal gas may be O₂ or N₂, for example.

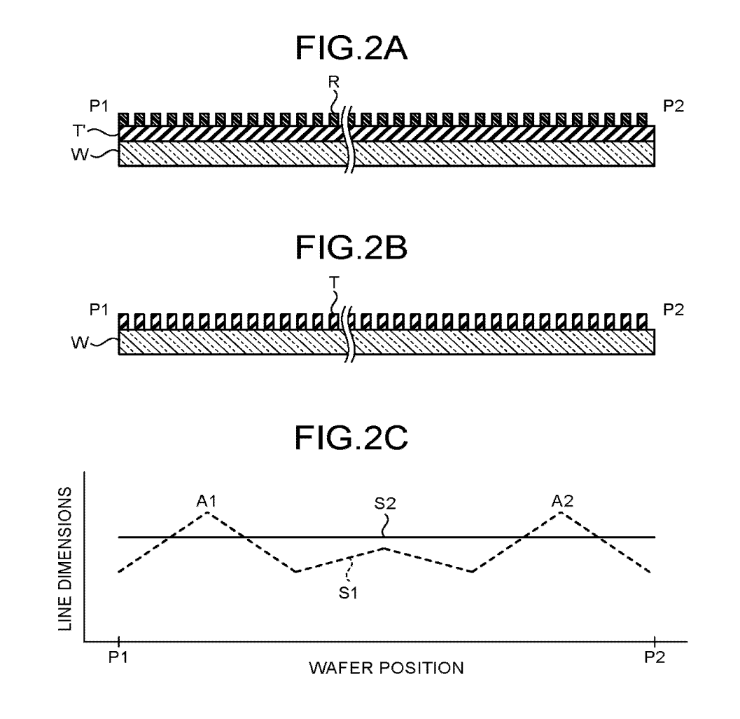

FIGS. 2A and 2B are cross-sectional views illustrating a manufacturing method of a semiconductor device to which the semiconductor manufacturing apparatus illustrated in FIG. 1A is applied, and FIG. 2C is a diagram illustrating the relationship between line dimensions and wafer positions at the semiconductor device illustrated in FIG. 2B. In the examples of FIGS. 2A and 2B, the semiconductor manufacturing apparatus illustrated in FIG. 1A is used as an etching apparatus.

Referring to FIG. 2A, a processed film T′ is formed on the wafer W. The processed film T′ may be an insulating film of SiO₂, a metallic film of Al or Cu, or a semiconductor film of polycrystalline silicon. A resist pattern R is formed on the processed film T′ by use of a photolithographic technique. The resist pattern R may be a line pattern or a hole pattern. Then, the processed film T′ is etched with the resist pattern R as a mask to form a processed pattern T on the wafer W.

In the etching process of the processed film T′, the semiconductor manufacturing apparatus illustrated in FIG. 1A can be used. At that time, the wafer W with the processed film T′ is placed on the stage 2, and fixed to the stage 2 by the electrostatic chuck 3. Then, while air is exhausted from the chamber 1 via the exhaust duct 14, the gas injector 9 injects the gas G1 and the gas injectors 5A to 5H inject the gas G2. Then, the gases G1 and G2 are converted into plasma to etch the processed film T′.

When the gas injector 9 injects only the gas the gas G1 is blown down to the center O of the wafer W. On the wafer surface, the gas G1 flows horizontally from the center O to side portions P1 and P2 of the wafer W. At that time, singularities A1 and A2 are generated in the flow of the gas G1 at the intermediate portion of the center O and the side portions P1 and P2 of the wafer W. Accordingly, when the processed pattern T is a line pattern, for example, the line dimensions of the processed pattern T become uneven at the singularities A1 and A2 as illustrated by a dotted line S1 in FIG. 2C.

Meanwhile, the gas injectors 5A to 5H inject the gas G2 while the gas injector 9 injects the gas G1, and the gas G2 can be blown to the side portions P1 and P2 of the wafer W or the intermediate portion between the center O and the side portions P1 and P2 of the wafer W. In addition, the gas G2 can be flown horizontally from the side portions P1 and P2 to the center O of the wafer W. At that time, the flow of the gas G1 can be tuned at the intermediate portion between the center O and the side portions P1 and P2 of the wafer W, thereby to eliminate the singularities A1 and A2 in the flow of the gas G1. Accordingly, as illustrated by a solid line 52 in FIG. 2C, the line dimensions of the processed pattern T can be made even from the center O to the side portions P1 and P2 of the wafer W.

In the etching process, when the gas injector injects only the gas G1 and the line dimensions become small at the singularities A1 and A2, the deposition gas can be used as the gas G2. Meanwhile, in the etching process, when the gas injector 9 injects only the gas G1 and the line dimensions become large at the singularities A1 and A2, the etching gas or the deposition removal gas can be used as the gas G2.

Meanwhile, in the film forming process, when the gas injector 9 injects only the gas G1 and the film thickness becomes small at the singularities A1 and A2, the deposition gas can be used as the gas G2. Meanwhile, in the film forming process, when the gas injector 9 injects only the gas G1 and the film thickness becomes large at the singularities A1 and A2, the etching gas or the deposition removal gas can be used as the gas G2.

### Second Embodiment

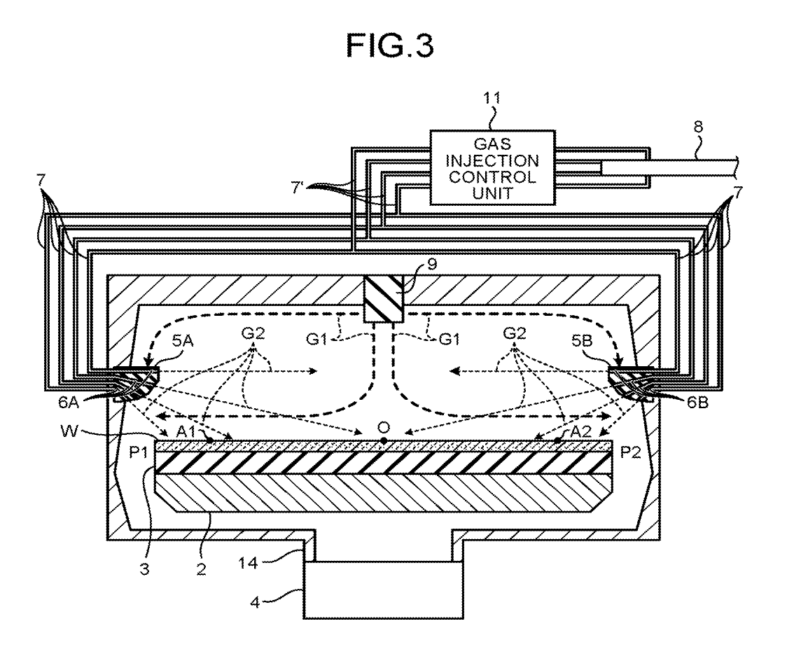

FIG. 3 is a schematic cross-sectional view of a semiconductor manufacturing apparatus according to a second embodiment.

In the configuration of FIG. 3, a gas injection control unit 11 is added to the configuration of FIG. 1A. The gas injection control unit 11 can control the flows of the gas G2 flowing through the branch tubes 7 into the gas injectors 5A and 5B at the injection angles θ1 to θ4. At that time, the gas injection control unit 11 is preferably provided on branch tubes 7′ that allow the branch tubes 7 dividing the gas G2 for the gas injectors 5A to 5H at the injection angles θ1 to θ4 illustrated in FIG. 1B to join together between the branch tubes 7 and the main tube 8.

Providing the gas injection control unit 11 to the configuration of FIG. 1A makes it possible to control the gas flow amounts at the injection angles θ1 to θ4. Accordingly, the flows of the gas G2 can be adjusted according to the positions of the singularities A1 and A2 on the wafer surface, which improves the uniformity of the processed pattern T on the wafer surface.

By providing the gas injection control unit 11 to the branch tubes 7′, even when the gas injectors 5A to 5H are arranged at the eight positions, one gas injection control unit 11 is sufficient. This decreases the gas injection control unit 11 in number as compared to the configuration in which the gas injection control units 11 are provided on the branch tubes 7.

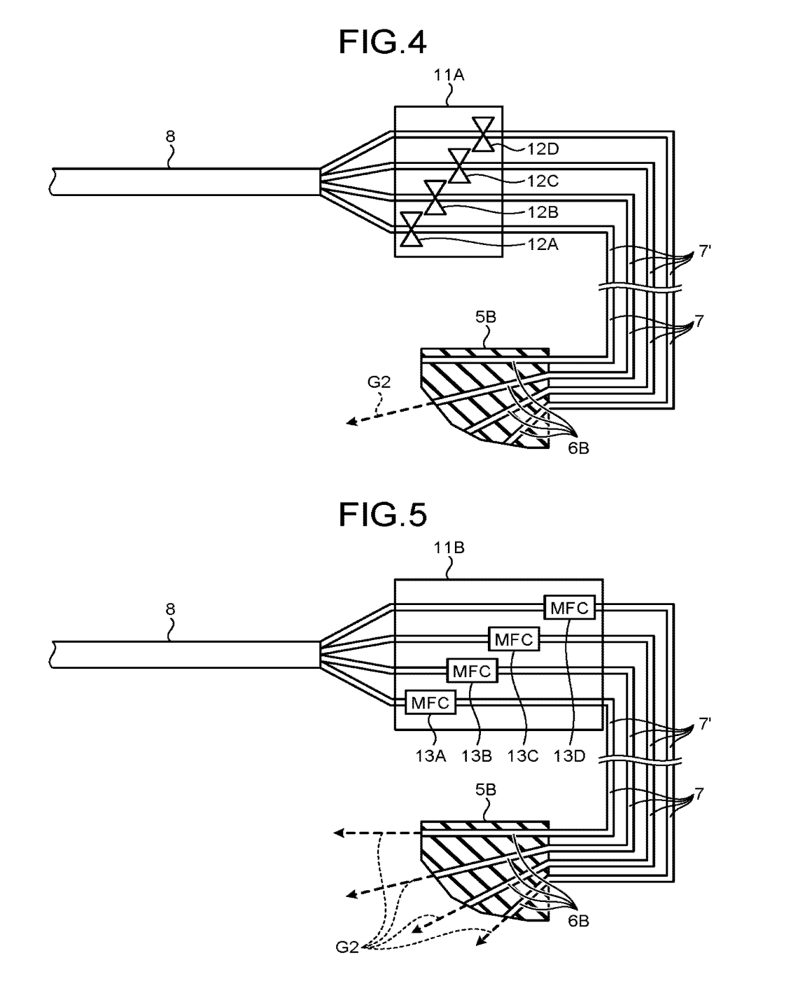

FIG. 4 is a diagram illustrating an example of the gas injection control unit illustrated in FIG. 3. In the example of FIG. 4, only the gas injector 55 is illustrated as a representative. However, the gas injection control unit can be applied to the gas injectors 5A and 5C to 5H in the same manner.

In the configuration of FIG. 4, a gas injection control unit 11A is provided. The gas injection control unit 11A has valves 12A to 12D provided on the branch tubes 7′ corresponding to the injection angles θ1 to θ4. The valves 12A to 12D can flow or stop the gas G2 at the injection angles θ1 to θ4. For example, by opening the valve 12B and closing the valves 12A, 12C, and 12D, it is possible to inject the gas G2 from the nozzle 6B at the injection angle θ3, and stop the injection of the gas G2 from the nozzle 6B at the injection angles θ1, θ2, and θ4. Accordingly, it is possible to increase the flow amount of the gas G2 at the injection angle θ3 and decrease the flow amount of the gas G2 at the injection angles θ1, θ2, and θ4 on the wafer surface.

FIG. 5 is a diagram illustrating another example of the gas injection control unit illustrated in FIG. 3.

In the configuration of FIG. 5, a gas injection control unit 11B is provided. The gas injection control unit 11B has mass flow controllers (MFC) 13A to 13D on the branch tubes 7′ corresponding to the injection angles θ1 to θ4. The mass flow controllers 13A to 139 can adjust the flow amounts of the gas G2 at the injection angles θ1 to θ4. For example, it is possible to increase the flow amount of the gas G2 from the nozzle 6B at the injection angle θ3 and decrease the flow amount of the gas G2 from the nozzle 6B at the injection angles θ1, θ2, and θ4. Accordingly, it is possible to increase the flow amount of the gas G2 at the injection angle θ3 and decrease the flow amount of the gas G2 at the injection angles θ1, θ2, and θ4 on the wafer surface.

### Third Embodiment

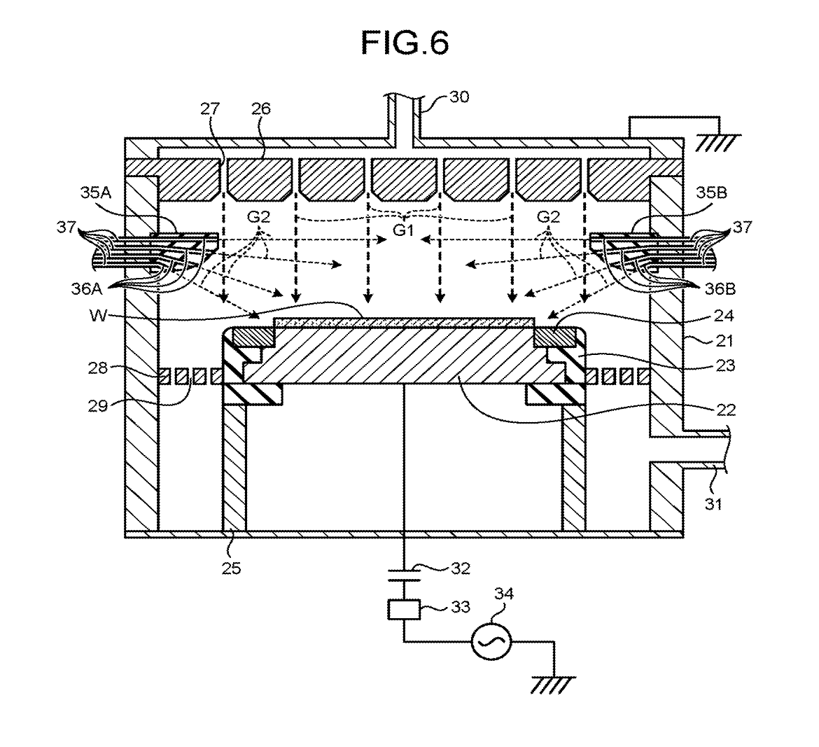

FIG. 6 is a schematic cross-sectional view of a semiconductor manufacturing apparatus according to a third embodiment. In the example of FIG. 6, a capacitance-coupled (parallel plate-type) plasma etching apparatus is taken.

Referring to FIG. 6, a chamber 21 contains a stage 22 holding the wafer W. The chamber 21 can be formed from a conductive material such as A1. The chamber 21 can be grounded. The stage 22 is held by a support body 25 within the chamber 21. An insulating ring 23 is provided around the stage 22. A focus ring 24 is embedded at a boundary between the stage 22 and the insulating ring 23 along the outer periphery of the wafer W.

The focus ring 24 prevents deflection of an electric field at the peripheral edge of the wafer W. The stage 22 is connected to a radio-frequency power supply 34 via a blocking capacitor 32 and a matching box 33 in sequence. The blocking capacitor 32 can reduce damage due to ion collision at the time of etching. The matching box 33 can have an impedance match with the load on the radio-frequency power supply 34. An exhaust pipe 31 is provided at the lower part of inside of the chamber 21. A baffle plate 28 is provided upstream of the exhaust pipe 31. The baffle plate 28 can adjust exhaust resistance in an exhaust system. The baffle plate 28 can be provided with an exhaust hole 29.

A shower head 26 is placed at the upper part of inside of the chamber 21, and gas injectors 35A and 35B are arranged on the side surfaces of the chamber 21. The shower head 26 can inject the gas 1 vertically from above the wafer W to the wafer surface. The shower head 26 can be provided with injection holes for injecting the gas G1. A pipe 30 is provided above the shower head 26 to supply the gas G1 to the shower head 26. The gas G1 can be a main gas to advance the plasma etching process in the chamber 21. The shower head 26 can be used as an upper electrode at the time of plasma generation. The stage 22 can be used as a lower electrode at the time of plasma generation.

The gas injectors 35A and 35B can inject the gas G2 of one and the same kind from the side portions to the center of the wafer W. The gas injectors 35A and 35B are provided with nozzles 36A and 36B to inject the gas G2. The nozzles 36A and 36B are set at N (N is an integer of or more) injection angles relative to an axis vertical to the wafer surface. FIG. 6 illustrates the example in which the nozzles 36A and 36B are set at four injection angles relative to the vertical axis. The nozzles 36A and 36B can be configured in the same manner as the nozzles 6A and 6B illustrated in FIG. 1A. The nozzles 36A and 36B at the injection angles are respectively connected to corresponding branch tubes 37 and the branch tubes 37 can join with main tubes.

While the air is exhausted from the chamber 21 via the exhaust pipe 31, the shower head 26 injects the gas G1 and the gas injectors 35A and 35B inject the gas G2. At that time, when the radio-frequency power supply 34 supplies radio-frequency power to the stage 22, the gases G1 and G2 are ionized to generate plasma on the wafer W. The etching process is performed by the plasma attacking the wafer W or reacting on the wafer W.

By injecting the gas G2 from the gas injectors 35A and 35B, it is possible to improve the uniformity of the pattern formed on the wafer W by plasma etching as compared to the case where the shower head 26 injects only the gas G1.

### Fourth Embodiment

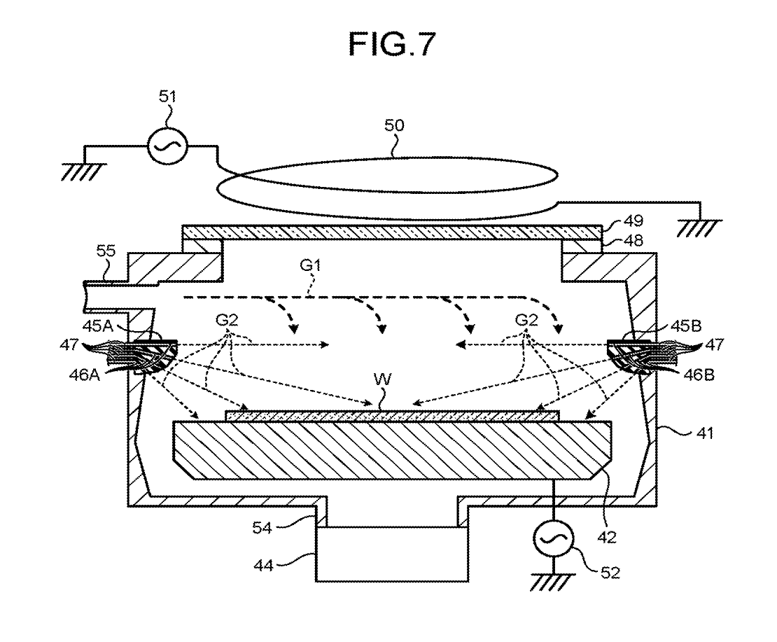

FIG. 7 is a schematic cross-sectional view of a semiconductor manufacturing apparatus according to a fourth embodiment. In the example of FIG. 7, an inductively-coupled plasma etching apparatus is taken.

Referring to FIG. 7, a chamber 41 contains a stage 42 holding the wafer W. The stage 42 is connected to a radio-frequency power supply 52. An exhaust pipe 4 is provided on the lower surface of the chamber 41. The exhaust pipe 54 is connected to a vacuum pump 44. The upper surface of the chamber 41 is opened. A radio-frequency introduction window 49 is placed on the upper surface of the chamber 41 via a support body 46. A radio-frequency antenna 50 is provided on the radio-frequency introduction window 49. The radio-frequency antenna 50 has one end grounded and the other end connected to a radio-frequency power supply 51. A gas introduction pipe 55 is provided on the side surface of the chamber 41. The gas introduction pipe 55 can horizontally inject the gas G1 above the wafer W. Gas injectors 45A and 45B are provided under the gas introduction pipe 55 on the side surfaces of the chamber 41.

The gas injectors 45A and 45B can inject the gas G2 of one and the same kind from the side portions to the center of the wafer W. The gas injectors 45A and 45B are provided with nozzles 46A and 46B to inject the gas G2. The nozzles 46A and 46B are et at N (N is an integer of 2 or more) injection angles relative to an axis vertical to the wafer surface. FIG. 7 illustrates the example in which the nozzles 46A and 46B are set at four injection angles relative to the vertical axis. The nozzles 46A and 46B can be configured in the same manner as the nozzles 6A and 6B illustrated in FIG. 1A. The nozzles 46A and 46B at the injection angles are respectively connected to corresponding branch tubes 47 and the branch tubes 47 can join with main tubes.

While the air is exhausted from the chamber 41 via the exhaust pipe 54, the gas introduction pipe 55 injects the gas G1 and the gas injectors 45A and 45B inject the gas G2. At that time, when the radio-frequency power supply 52 supplies radio-frequency power to the stage 42 and the radio-frequency power supply 51 supplies radio-frequency power to the radio-frequency antenna 50, the gases G1 and G2 are ionized to generate plasma on the wafer W. The etching process is performed by the plasma attacking the wafer W or reacting on the wafer W.

By injecting the gas G2 from the gas injectors 45A and 45B, it is possible to improve the uniformity of the pattern formed on the wafer P by plasma etching as compared to the case where the gas introduction pipe 55 injects only the gas G1.

In the example of FIG. 7, the inductively-coupled plasma etching apparatus is taken, but the present invention may also be applied to a micro-wave ECR (electron cyclotron resonance) plasma etching apparatus. In addition, the plasma etching apparatus is taken in the foregoing embodiments, but the present invention may be applied to a plasma CVD apparatus.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor manufacturing apparatus, comprising:
a chamber configured to contain a wafer;
a stage configured to hold the wafer in the chamber; and
a first gas injector that is set at N (N is an integer of 2 or more) injection angles relative to an axis vertical to a wafer surface and is capable of injecting a gas of one and the same kind at the N injection angles from a side portion to a center of the wafer.

2. The semiconductor manufacturing apparatus of claim 1, wherein the N injection angles are set in one and the same vertical plane.

3. The semiconductor manufacturing apparatus of claim 1, wherein the first gas injector is arranged on the side portion of the wafer at M (M is an integer of 2 or more) positions.

4. The semiconductor manufacturing apparatus of claim 3, further comprising:
one main tube that sends out the gas; and
M×N branch tubes that divide the gas sent out from the main tube into M×N branches.

5. The semiconductor manufacturing apparatus of claim 1, further comprising an injection control unit that controls injection of the gas at the N injection angles respectively.

6. The semiconductor manufacturing apparatus of claim 5, wherein the injection control unit includes N valves provided corresponding to the N injection angles.

7. The semiconductor manufacturing apparatus of claim 5, wherein the injection control unit includes N mass flow controllers provided corresponding to the N injection angles.

8. The semiconductor manufacturing apparatus of claim 1, further comprising a second gas injector that injects a gas from above the wafer to the wafer surface.

9. The semiconductor manufacturing apparatus of claim 8, wherein the gas injected from the first gas injector is a tuning gas that adjusts a singularity in the flow of the gas injected from the second gas injector on the wafer surface.

10. The semiconductor manufacturing apparatus of claim 8, wherein
the second gas injector injects and blows downward the gas from above the wafer to the center of the wafer, and
the first gas injector blows the gas to the side portion of the wafer or an intermediate portion between the center and the side portion of the wafer.

11. The semiconductor manufacturing apparatus of claim 1, further comprising a plasma generation unit that generates plasma above the wafer.

12. A manufacturing method of a semiconductor device that processes a wafer while injecting a gas onto the wafer, comprising:
setting N (N is an integer of 2 or more) injection angles relative to an axis vertical to a wafer surface from a side portion to a center of the wafer; and
injecting a first gas at the set N injection angles onto the wafer at the same time.

13. The manufacturing method of a semiconductor device of claim 12, wherein the first gas at the set N injection angles is injected from M (M is an integer of 2 or more) positions on the side portion of the wafer onto the wafer at the same time.

14. The manufacturing method of a semiconductor device of claim 13, wherein the first gas is injected onto the wafer at approximately uniform flow amounts from M directions symmetrical with respect to the center of the wafer at the same time.

15. The manufacturing method of a semiconductor device of claim 13, wherein injecting the first gas at the set N injection angles comprises dividing the first gas supplied from one and the same gas supply source into M×N branches, the first gas being injected through the divided branches onto the wafer at the same time.

16. The manufacturing method of a semiconductor device of claim 12, wherein injecting the first gas at the set N injection angles comprises adjusting the flow amounts at the N injection angles.

17. The manufacturing method of a semiconductor device of claim 12, further comprising injecting a second gas from above the wafer to the wafer surface.

18. The manufacturing method of a semiconductor device of claim 17, wherein a plasma process is performed while injecting the first gas and the second gas onto the wafer.

19. The manufacturing method of a semiconductor device of claim 18, wherein the first gas is a tuning gas that adjust a singularity in the flow of the second gas on the wafer surface.

20. The manufacturing method of a semiconductor device of claim 17, wherein
the second gas is blown down from above the wafer to the center of the wafer, and
the first gas is blown to the side portion of the wafer or an intermediate portion between the center and the side portion of the wafer.
